(19) United States
(12) Patent Application Publication
(10) Pub. No.: US 2023/0086102 A1
(43) Pub. Date: Mar. 23, 2023

(54) Methods of Manufacturing a Parallel, Simplified, Formerless Multi-Coil Cylindrical Superconducting Magnet Structure, and a Structure as May Be Manufactured by Such Methods

(71) Applicant: Siemens Healthcare Limited, Camberley (GB)

(72) Inventor: Simon James Calvert, Chipping Norton (GB)

(73) Assignee: Siemens Healthcare Limited, Camberley (GB)

(21) Appl. No.: 17/950,224

(22) Filed: Sep. 22, 2022

(30) Foreign Application Priority Data
Sep. 23, 2021 (GB) 2113579.3

(51) Int. Cl. H01F 41/04; H01F 6/06; H01F 41/098; G01R 33/3815; G01R 33/38

(52) U.S. Cl. CPC H01F 41/048; H01F 6/06; H01F 41/098; G01R 33/3815; G01R 33/3802

(57) ABSTRACT

Techniques are disclosed with respect to the manufacture of formerless, multi-coil, cylindrical superconducting magnets, and a formerless, multi-coil, cylindrical superconducting magnet structure as may be formed by such techniques.

### CROSS-REFERENCE TO RELATED APPLICATIONS

The present application claims priority to and the benefit of United Kingdom patent application no. GB 2113579.3, filed on Sep. 23, 2021, the contents of which are incorporated herein by reference in its entirety.

### TECHNICAL FIELD

The present disclosure relates to methods of manufacturing formerless multi-coil cylindrical superconducting magnets, and to cylindrical superconducting magnets manufactured by such methods. Such a magnet may be employed as a main magnetic field generator in a magnetic resonance imaging (MRI) system.

### BACKGROUND

Conventionally, cylindrical superconducting magnets have been manufactured with formers; or with external sleeves. Recent “formerless” magnets, composed of alternating annular coils and annular spacers, are known, but may be manufactured by a complex and unreliable manufacturing method. The present disclosure aims to provide simpler and more reliable manufacturing methods for formerless cylindrical superconducting magnets, and to provide improved formerless cylindrical superconducting magnets.

### SUMMARY

Aluminum or composite material formers are commonly used on “wet” magnets, i.e. those cooled by direct contact with a liquid cryogen, and “dry” magnets, i.e. those not cooled by direct contact with a liquid cryogen. Superconducting wire is wound onto a former and can be left un-impregnated, or can be impregnated with epoxy resin, for example. Such magnet structures can also be wet-wound, i.e. wound using wire which is already coated in epoxy resin rather than being vacuum impregnated after winding. While such use of a former gives good precision in coil size, shape, and position, the formers are expensive and necessarily occupy space on the radially-inner surface of the coils, increasing the required diameter of the coils and moving the coils away from the imaging volume. Both of these effects increase the number of turns of wire required. Bearing in mind the required geometry of the coil layout, an increase in diameter of the coils requires an increased axial spacing between the coils. These effects increase the wire cost and the overall length and mass of the magnet.

Externally sleeved coils have been employed in which solenoids have external machined sleeves to constrain them and to reduce hoop stress. The required sleeves tend to be expensive to manufacture, particularly when made from forgings. The required coil machining is also expensive. Assemblies comprising multiple coils can also be externally sleeved, but such arrangements have even greater cost and complexity, as the sleeve is typically formed in several pieces to allow assembly, and all coils must be machined or molded to very high precision.

Certain formerless coils are known and may for example be known as “serially bonded magnets” or “SBM magnets.” SBM magnets can be assembled using individual coils stacked with annular spacers, but such methods cause long manufacturing time and manufacturing tolerances stack up in the magnet assembly, making this approach unsuitable for volume-manufactured magnets.

The present disclosure accordingly seeks to provide methods of manufacturing formerless, multi-coil, cylindrical superconducting magnets, which are simpler and more precise than known methods, and may be implemented with a reduced cost compared to known methods. The present disclosure also provides formerless, multi-coil, cylindrical superconducting magnets as may be produced by such methods.

The present disclosure accordingly provides methods and apparatus as defined in the embodiments of the present disclosure, including the claims.

### BRIEF DESCRIPTION OF THE DRAWINGS

The above, and further, objects, characteristics and advantages of the present disclosure will become more apparent from the following discussion of certain embodiments thereof, given by way of non-limiting examples, in conjunction with the accompanying drawings, wherein:

FIG. 1 illustrates an example of a mandrel as may be employed in an embodiment of the present disclosure;

FIG. 2 illustrates an example step in a method of an embodiment of the present disclosure in which spacer rings are fitted to the mandrel of FIG. 1;

FIGS. 3a and 3b illustrate example methods of fixing spacer rings to the wrapper in an embodiment the present disclosure, in which a spacer ring is attached to the mandrel in a predetermined axial position;

FIG. 4 illustrates an example later step in a method of an embodiment of the present disclosure, in which superconducting coils have been wound onto the mandrel into volumes defined by the spacer rings;

FIG. 5 illustrates an example completed formerless, multi-coil, cylindrical superconducting magnet as may be manufactured by a method of an embodiment of the present disclosure;

FIG. 6a shows a detailed view of an example wet-wound or resin-impregnated material used to make a wrapper fitted to the mandrel as shown in FIG. 2, in an embodiment of the present disclosure;

FIG. 6b illustrates an alternative embodiment to form a thin wrapper by using thin composite strips wound in spirals;

FIG. 6c illustrates another alternative embodiment to form a thin wrapper by using misaligned strips of composite resin-impregnated cloth material;

FIG. 7 illustrates a step in an alternative method, according to another embodiment of the present disclosure;

FIG. 8 illustrates an example completed formerless, multi-coil, cylindrical superconducting magnet as may be manufactured by a method of an embodiment of the present disclosure;

FIG. 9 shows detail of an example friable pin as may be used to align the spacers in apparatus used in a step of a method according to an embodiment of the present disclosure; and

FIG. 10 shows an example embodiment in which layers of cloth are applied to the mandrel prior to winding of a coil.

FIG. 8 is shown as an axial transect and the remaining drawings are shown in full- or partial-axial cross-section.

### DETAILED DESCRIPTION OF THE DISCLOSURE

Known methods exist for the manufacture of SBM magnets. These typically involve stepped mandrels, in which the outer radial surface of the mandrel is stepped; spacer rings of appropriate dimensions are manufactured and butted up against those steps to ensure correct positioning, and coils wound between the spacer rings so positioned.

However, the stepping of the mandrel effectively increases the mandrel thickness, and leads to increased internal diameter of the coils, in turn increasing the cost of the wire, and commensurately increasing the axial length, mass, and cost of the magnet. By relying on positioning of the spacers by simply abutting the spacers against steps, some movement of the spacers may occur during the winding of coils, with the result that the coils of the magnet are not precisely positioned in the finished structure. The present disclosure enables the use of an unstepped mandrel. Positively-located spacers ensure the correct location and spacing of the coils in the finished magnet structure.

The present disclosure aims to provide a “parallel” SBM magnet, i.e. one with a constant, or approximately constant, inner diameter. This may be achieved by use of a mandrel that is not stepped but has parallel walls, or walls that are slightly tapered to aid mandrel extraction. Such a structure provides certain advantages, e.g. reducing wire cost as compared to a magnet formed on a stepped mandrel, and eliminates steps in the finished structure, which have been found to cause regions of high stresses. The inner diameter of individual coils can be slightly increased, while maintaining the constant or slightly tapered inner diameter of the structure as a whole, by adding layers of glass fiber cloth onto the mandrel before the coil is wound. This may be required to achieve the required homogeneity while optimizing the amount of wire required. More details of this optional arrangement are provided below, in the description of FIG. 10.

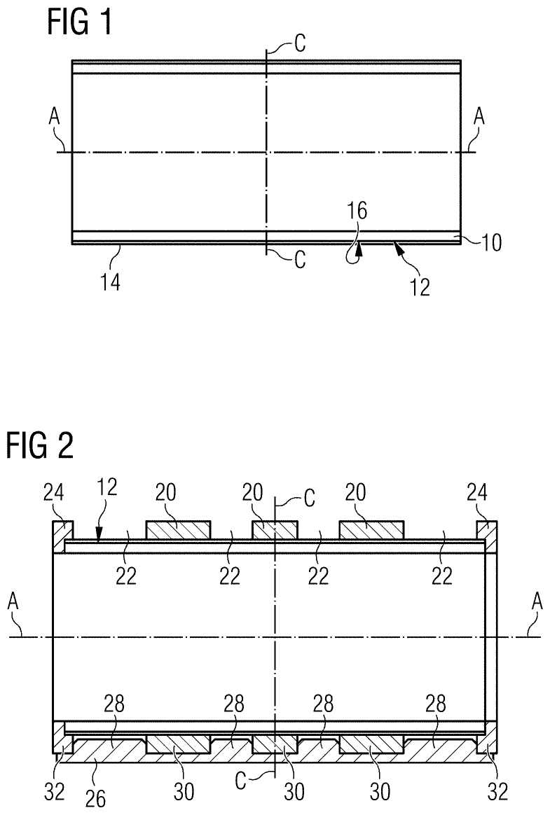

FIG. 1 shows an example mandrel as may be used in a method of the present disclosure, in axial cross-section. The mandrel 10 has a thin composite wrapper wound onto it labelled as 14. The wrapper may be wound onto the mandrel 10 either using resin-impregnated cloth or a wet-wound approach; the wrapper is then cured and machined to a cylinder before assembly of the other components. The mandrel 10 is essentially rotationally symmetrical about axis A-A and reflectively symmetrical about center plane C-C. The mandrel 10 has parallel sides, or approximately parallel sides with a small taper. In the present description, “axial” and similar terms will denote a direction parallel to axis A-A, while “radial” and similar terms will denote a direction perpendicular to axis A-A.

The mandrel 10 itself is a hollow cylinder, in some embodiments having a slight conical taper. It may be of aluminum, stainless steel, or some other suitable material that is capable of holding a fine finish. The mandrel 10 may have parallel radially outer surfaces, or the outer cylindrical surface 12 may be slightly tapered. Such a taper may have e.g. any suitable change in radius over the length of the mandrel, e g 0.5 mm, with the mandrel typically being 1000 mm-2000 mm long, depending on the magnet type. However, the mandrel 10 is essentially cylindrical, and references herein to the mandrel being “cylindrical” cover embodiments in which the outer cylindrical surface of the mandrel 10 is tapered by any suitable amount, e.g. up to 1 degree, up to 1.5 degrees, up to 5 degrees, etc. The taper of the mandrel 10 makes the eventual mandrel extraction easier.

The mandrel 10 has a thin composite wrapper 14 wound onto it. For example, such a wrapper may be formed by winding onto the mandrel 10 either using carbon- or glass-fiber cloth pre-impregnated with a thermosetting resin, or a wet-wound approach in which a carbon- or glass-fiber filament is wetted with a thermosetting resin as it is wound onto the mandrel. The resin-impregnated material of the wrapper is then cured and machined to a cylinder before assembly of the other components.

The wrapper 14 may have any suitable radial thickness, e.g. 0.51-2 mm. The wrapper 14 should preferably not be more than 2 mm, as this will have an impact on the inside of the coil and may cause de-lamination. The wrapper 14 may be of resin-impregnated glass cloth of various constructions and may e.g. be separated from the outer cylindrical surface 12 of the mandrel 10 by a release layer 16. The release layer 16 may be of any appropriate material to reduce or prevent adhesion between the wrapper 14 and the outer cylindrical surface 12 of the mandrel 10. Example materials include a layer of polytetrafluoroethylene (PTFE) that is applied to the outer cylindrical surface 12 of the mandrel 10; or a dry-wound release cloth.

FIG. 2 shows a later stage in a method according to an embodiment of the present disclosure. The spacer rings 20 are fitted to the mandrel of FIG. 1. In addition, end flanges 24, such as metal rings, are fitted to the ends of the mandrel. An alignment comb tool 26 provides protrusions and recesses and ensures that the spacer rings 20 are in correct axial position prior to fixing to the wrapper.

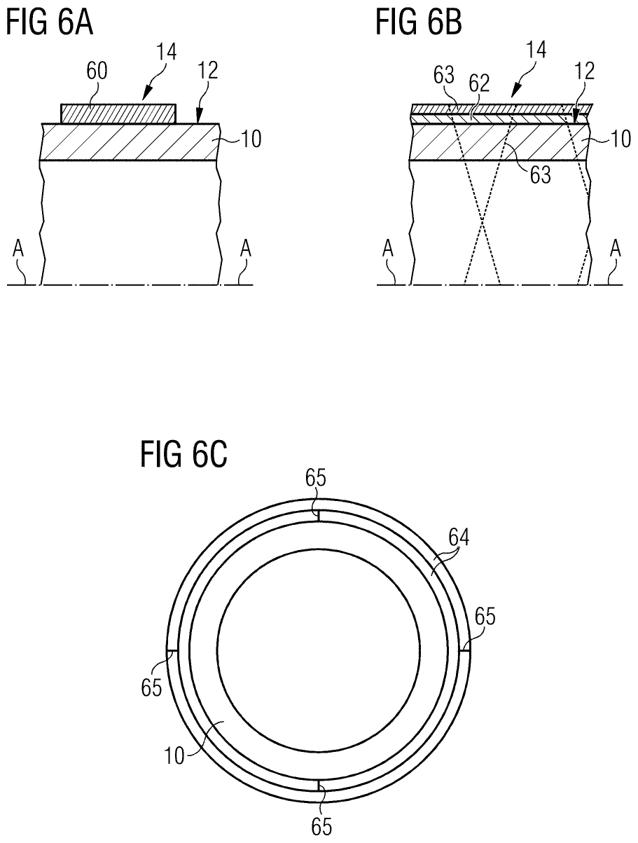

FIG. 6a shows a view of a wrapper 14 of impregnated cloth 60 wrapped around the mandrel 10 as shown in FIG. 2; and FIG. 6b illustrates an alternative embodiment of a wrapper, in which the wrapper 14 is formed by using two layers 62, 63 of thin composite strips wound in a spiral. FIG. 6c shows another alternative, using layers of separate strips 64 of resin-impregnated cloth, each having a length of approximately half the circumference of the mandrel 10, positioned such that joints 65 between the strip ends 66 do not align in adjacent layers.

Referring again to FIG. 2, the annular spacers 20 are located in predetermined axial positions along the outer cylindrical surface 12 of the mandrel 10. Gaps 22 between the annular spacers 20 define volumes of predetermined dimensions for the winding of coils. In the illustrated embodiment, end flanges 24 are provided, extending over the ends of the mandrel 10. These flanges may cooperate with annular spacers 20 to define endmost gaps 22, which define volumes of predetermined dimensions for the winding of end coils. Also illustrated is an alignment comb tool 26. Such alignment tools may be positioned at three or more locations around the magnet structure to ensure correct positioning of the spacers 20, and so to ensure correct positioning of the coils. As illustrated, and in this example, the alignment comb tool 26 has a number of projections 28 and recesses 30. The recesses 30 correspond to predetermined required positions for annular spacers 20. The protrusions 28 correspond to predetermined required positions for gaps 22, and so also for coils to be wound into the gaps. The alignment comb tool 26 comprises further recesses 32, which correspond to predetermined locations and dimensions of end flanges 24.

In use, annular spacers 20 are slid over the wrapper 14. End flanges 24 are attached in position. This may be by applying a force of tension or compression between the two end flanges. Then a number, e.g. at least three, of alignment comb tools 26 are aligned by further recesses 32 to the positions of end flanges 24, thereby defining predetermined locations for annular spacers 20. The annular spacers 20 are then fixed at these predetermined positions, by a method to be described below, to define gaps 22 for the winding of coils.

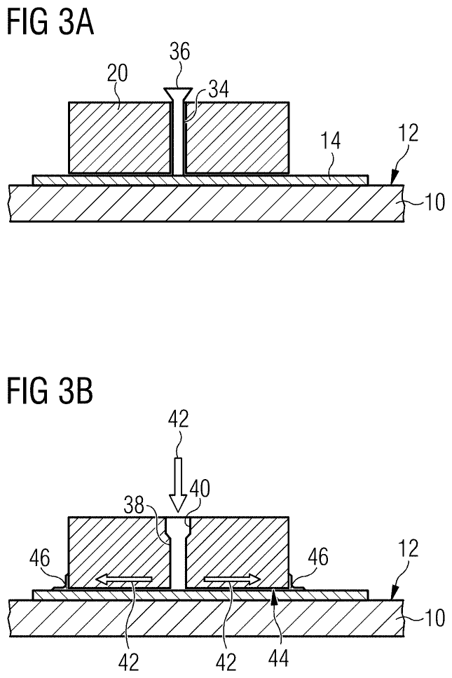

FIG. 3a illustrates a first arrangement and method for fixing annular spacers 20 in position over the wrapper 14 on the radially outer surface 12 of the mandrel 10. At each of several positions around the circumference of each annular spacer 20, a threaded through hole 34 is provided. According to the embodiment, the through holes 34 may be threaded in the material of the annular spacer 20, or a threaded insert may be provided to provide a threaded through holes 34. In each through hole 34, a screw 36 is provided, with a head or other suitable arrangement for being tightened with an appropriate tool, such as screwdriver, hex key, spanner etc. Each screw 36 is tightened onto the wrapper 14, and so also onto the mandrel 10 sufficiently to retain the spacer 20 in a fixed, predetermined position with respect to the mandrel 10, and with respect to other spacers 20. As will be apparent to those skilled in the art, proper axial centering of the spacer 20 will be more readily achieved by tightening screws 36 in such an order that distanced screws are tightened one after the other, rather than adjacent screws, and that very little torque should be applied initially, at least until all screws are tightened to an initial extent. The screws may have sharp ends to bite into the wrapper to ensure good alignment. More torque may then be applied to the screws, in an appropriate order, whereby to ensure that the spacers 20 are retained in position during subsequent steps of winding, impregnating, and curing magnet coils, without tightening the screws 36 so tightly that damage or permanent deformation is caused to the mandrel 10 or spacer 20. Depending on the material selected for the wrapper, radially inner ends of screws 36 may be pointed, or domed, or otherwise shaped to ensure positive location of spacers 20 with respect to mandrel 10, but piercing of the wrapper 14 should be avoided to prevent damage to the radially outer surface 12 of the mandrel 10. Similarly, screws 36 should be of a material chosen to minimize the chance of damage to the wrapper 14 or the mandrel 10. The wrapper 14 may form ground plane insulation for the coils, and may also add structural reinforcement for the bonding of the coils to the spacer rings.

FIG. 3b illustrates a second arrangement and method for fixing annular spacers in position over the wrapper 14, on the radially outer surface 12 of the mandrel 10. At each of several positions around the circumference of each annular spacer 20, a through hole 38 is provided. At the radially outer end 40 of the through hole, an interface shaping may be provided. A hardening material is introduced through holes 38, in the directions of arrows 42. This may be a fast-setting glue; an epoxy resin or any other suitable material. The hardening material may e.g. be introduced through the through holes 38 in such quantity as to cover most, or all, of a radially inner surface 44 of the spacer 20, and so to provide an effective bond between wrapper 14 and spacer 20. The hardening material should preferably not permeate between wrapper 14 and mandrel 10, and should not provide a bond to the surface 10 of the mandrel 10. It may be found helpful to apply sealing tape 46 to seal joints between the spacer 20 and the wrapper 14 to prevent hardening material from leaking out from between the spacer 20 and the wrapper 14, and to encourage formation of an adhesive bond over the whole radially inner surface of the spacer 20. Once a suitable quantity of hardening material has been introduced, the hardening material is caused or allowed to harden. The spacer 20 is thereby retained in a predetermined position with respect to wrapper 14, and so also to mandrel 10.

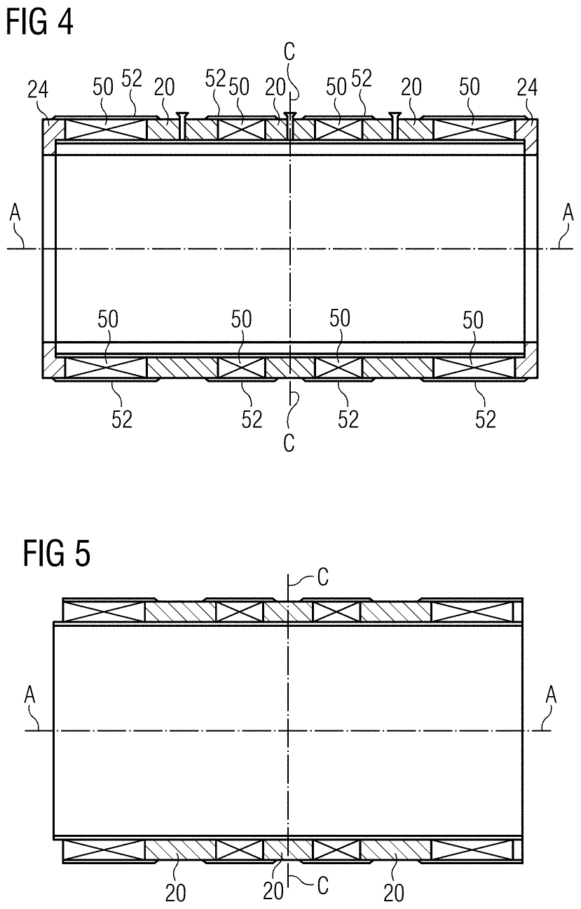

FIG. 4 shows the spacer rings 20 and end flanges 24 fixed in their predetermined positions with respect to wrapper 14 and mandrel 10, with coils of wire wound into the gaps 22 defined between spacers 20 and between end flanges 24 and an adjacent spacer 20. Such coil winding may proceed in a manner familiar to those skilled in the art, resulting in coils 50. As may be required, and as may be apparent to those skilled in the art, layers of overbind material 52 may be provided on the radially outer surface of the coils, extending at least partially over radially outer surfaces of adjacent spacers 20 to improve mechanical integrity, and to reinforce interface joints between coils 50 and spacers 20. Such overbind material may be of glass fiber cloth; carbon fiber cloth, or a wire of aluminum, copper, or stainless steel; or any other suitable material as may appear expedient to one skilled in the art. The coils, and any overbind material when provided, may be impregnated by a hardening material such as an epoxy resin, by methods as will be apparent to those skilled in the art, to complete the magnet assembly.

The wrapper 14 provides robust electrical insulation between the coils and metal components inside the coils, both during manufacture and once installed within an MRI system. The wrapper 14 also protects the inside of the coils 50 from mechanical damage and is bonded to the spacers 20, so as to prevent cracking at the interface between the coils 50 and the spacers 20.

FIG. 5 shows an axial cross-section of such a completed magnet assembly, removed from the mandrel. The completed magnet is shown, impregnated and with tooling removed.

Once the structure has been impregnated with an impregnant such as e.g. epoxy resin or equivalent, the impregnant is caused or allowed to harden. The mandrel 10 is then removed from the assembly. Since the wrapper 14 prevents any bonding to the mandrel, this is a matter of mechanically pulling the mandrel with respect to the magnet structure. Such withdrawal of the mandrel will be facilitated if the radially outer surface 12 of the mandrel is tapered in the axial direction. Such taper will need to be taken into account when calculating the required sizes and locations of coils 50, and the axial taper is e.g. of an angle of less than one degree.

FIGS. 6a, 6b, 6c illustrate alternative methods for forming the wrapper 14 over the radially outer surface of the mandrel 10.

In the example of FIG. 6a, a resin-impregnated cloth or wet-wound filament is used to form the wrapper 14. A release layer may be applied to the radially outer surface 12 of the mandrel 10. This may be any suitable coating or treatment to which resin used in the formation of wrapper 14 does not adhere. Layers of resin-impregnated cloth 60 are wound onto the radially outer surface 12 of the mandrel 10, over the release layer. The resin-impregnated cloth 60 may be glass fiber cloth, carbon fiber cloth, or any other suitable material as may be expedient. The cloth may be dipped into liquid uncured resin prior to winding, or may be wound dry, with liquid uncured resin being applied later by a suitable method. The resin is then caused, or allowed, to cure, and once hardened, may be machined to a smooth cylindrical surface, thereby to form wrapper 14 discussed above.

In the example of FIG. 6b, strips 62 of preformed composite material or resin-impregnated cloth are wound onto the radially outer surface 12 of the mandrel 10. In this illustrated example, two layers of strip are provided. In an embodiment, each layer comprises a single strip wound spirally over the length of mandrel 10, with suitable retaining means provided to hold respective ends of the strip in position. As illustrated, at least two layers of strips 62 are provided, with the second layer of strips wound spirally in the opposite direction to the direction of winding the first layer. This ensures that gaps 63 between turns in one layer of strips only align with gaps 63 between turns in another layer of strips over a very small area. Further layers of strips 62 may be provided, but it may be particularly advantageous to provide two layers.

FIG. 6c shows another alternative, using layers of separate strips 64 of resin-impregnated cloth each having a length of approximately half the circumference of the mandrel 10, positioned such that joins 65 between strip ends 66 do not align in adjacent layers.

In another alternative, wrapper 14 may be provided by winding a filament of glass fiber or similar, which may be coated with uncured resin prior to winding, or may be wound dry and impregnated with resin during the same step that the coils are impregnated with resin.

The wrapper 14 serves to protect the mandrel 10 from damage by means used to affix spacers 20 in place, such as screws or adhesive. The wrapper provides a robust, smooth surface to assist with removal of the mandrel 10 from the completed magnet structure, and the wrapper provides reinforcement to joints between coils 50 and spacers 20. The wrapper also serves as a ground-plane insulation and is a structural reinforcement for coil-spacer bonds.

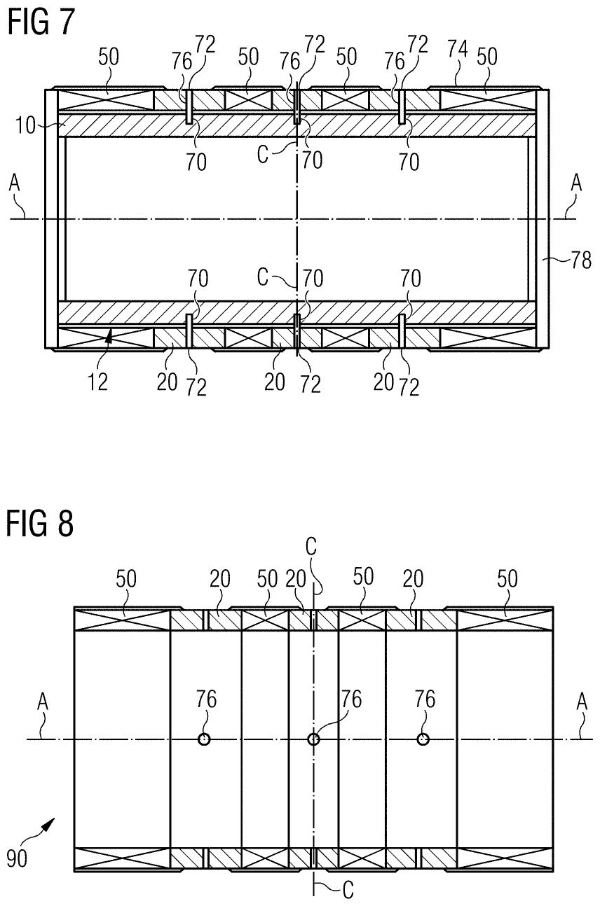

FIG. 7 illustrates another embodiment of the present disclosure, in which spacers 20 are pegged into position using friable pins 72 inserted through though-holes 76 in the spacers 20 into recesses 70 in the radially outer surface 12 of the mandrel 10. That is, the friable pins 72 are used to fix spacer rings 20 to the mandrel, and end plates 78 are used in place of end flanges 24. In such embodiments, the wrapper 14 discussed above may be found unnecessary, or may need to be adapted to accommodate the friable pins 72. As described above, the mandrel 10 may be slightly tapered to aid withdrawal from a completed magnet assembly. Friable pins 72 may be e.g. grooved or otherwise weakened at a level corresponding to the eventual surface of the mandrel to ensure that they fracture at the mandrel outer surface when the mandrel is withdrawn from the magnet. End plates 78 are implemented in place of the end flanges 24 of FIG. 2, but have an equivalent function.

Mandrel 10 is provided with a release layer 16, which may, as discussed above, be any suitable surface treatment on its radially outer surface 12 to avoid bonding of thermosetting resin to the mandrel. A wrapper 14 may be provided, as discussed above, but any such wrapper will need to be provided with holes which align with recesses 70 in the mandrel 10. Spacers 20, themselves comprising through holes 76, are then positioned over the radially outer surface 12 of the mandrel, and over any wrapper 14 that may be provided. The through holes 76 are arranged such that, when aligned with corresponding recesses 70 in the mandrel 10, the relevant spacer is accurately located in its predetermined position. Once through holes 76 and recesses 70 are aligned, friable pins 72 are passed through the through holes partially into the recesses 70. A sufficient length of each friable pin 72 remains within the through hole 76 of the spacer 20 to retain it in position. In an embodiment, at least three through holes 76 are provided in each spacer, distributed around the circumference thereof, with corresponding recesses 70 provided in the mandrel 10.

With spacers 20 retained in position in this way, and end flanges 24 or end plates 78 in position, gaps are thereby defined into which coils 50 may be wound, by any of the methods described above.

FIG. 7 shows an assembly according to an embodiment of the present disclosure, at the stage that coils 50 have been wound, and overbind 74 layers, such as of glass fiber cloth, have been applied over the coils. An impregnation step will follow, as will be understood by those skilled in the relevant art, in which coils 50 and overbind layers 74 are impregnated with a thermosetting resin, unless the coils 50 and overbind 74 were wet wound. That is, unless the coils 50 and overbind 74 were wound of wire, or cloth, respectively, which was already coated with a thermosetting resin.

The thermosetting impregnant of coils 50 and overbind 74 is caused or allowed to cure, and then the end flanges 24 or end plates 78 are removed, and the mandrel 10 withdrawn.

According to these embodiments of the present disclosure, friable pins 72 are located, partially within through holes 76 in spacers 20, and partially within recesses 70 in the mandrel 10.

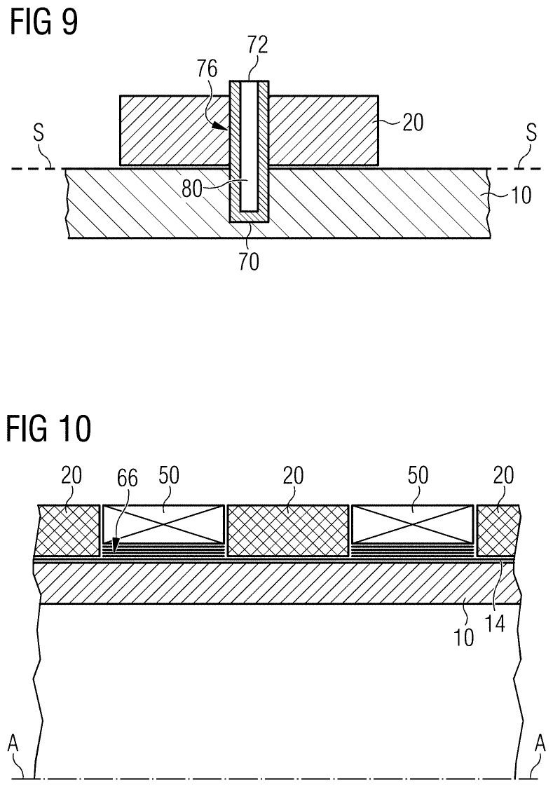

FIG. 9 shows these features in more detail. FIG. 9 is a partial axial cross-section of an embodiment similar to that shown in FIG. 7. When mandrel 10 is withdrawn from the magnet structure, the mandrel 10 is displaced in the axial direction, causing a cylindrical shear “plane” S-S at the radially outer surface of the mandrel 10. While friable pins 72 should be tight-fitting into through holes 76 and recesses 70, the friable pins 72 should also be robust enough to hold the respective spacer firmly in position during the process to wind and impregnate the coils 50, and yet be friable such that the friable pins 72 are fractured by withdrawal forces applied to mandrel 10. In the example shown in FIG. 9, the inventors have found it advantageous to provide each pin with a hollow 80 for most of its length. This limits the amount of material in each pin and reduces the shear force required to sever each pin as compared to a similar solid pin. The outer surface of each pin may e.g. be notched, grooved, or otherwise weakened at a position corresponding to the shear plane S-S in the complete structure to further reduce the force required to sever the pin while retaining sufficient strength to retain spacers 20 in position during winding and impregnation of coils 50. The pins may be of any suitable material, e.g. a plastic material, such as nylon, PTFE, or a suitable composite material. The material should be chosen such that it does not produce shards upon fracturing of the pin.

It may be useful to provide a coarse screw thread on an outer and/or inner surface of each hollow pin 72 to provide for extraction of the pin by a suitable tool, such as a stud extractor.

In alternative embodiments of a method of the present disclosure, pins 72 need not be friable, and are extracted from the spacers 20 after curing of the thermosetting resin, and before withdrawal of the mandrel 10.

FIG. 8 illustrates a completed formerless, parallel, multi-coil, cylindrical superconducting magnet 90 as may be manufactured by a method of the present disclosure, in which shear pins 72 are used to retain the spacer rings in position during manufacture of the magnet. These shear pins 72 are sheared during mandrel extraction. The shear pins 72 may e.g. be weakened by a groove or similar to ensure that the pins shear at the correct position during mandrel extraction. That is, the friable pins 72 are used to fix spacer rings, the friable pins 72 are sheared during mandrel extraction, and may e.g. be weakened, such as by a groove, to ensure that the friable pins 72 shear at the correct position during mandrel extraction.

FIG. 8 illustrates an axial transect of a completed magnet structure 90 according to this embodiment of the disclosure. In the illustrated embodiment, four through holes 76 are provided in each spacer 20, distributed around the circumference thereof. Parts of sheared pins 72 may remain within the through holes 76, or it may be preferred to remove the pins 72 before the magnet structure 90 is built into a cylindrical superconducting magnet. The parts of sheared pins could be left in the structure provided that they are of a compatible material.

FIG. 10 shows an example embodiment in which layers of cloth 66 are applied to the mandrel 10 prior to winding of a coil 50, so as to increase the diameter of the coil 50 without requiring a variance in the diameter of the mandrel 10. The layers of cloth may be impregnated with uncured resin prior to winding onto the mandrel 10, a so-called “pre-preg” cloth, or may be wound dry and impregnated with resin during the same step that the coils are impregnated with resin. Similarly, the same effect may be achieved by winding a filament of glass fiber or similar, which may be coated with uncured resin prior to winding, or may be wound dry and impregnated with resin during the same step that the coils are impregnated with resin. Once the cloth or filament is wound to the required thickness over the mandrel, to provide the required inner diameter of the coil, wire is wound over the cloth or filament to constitute a superconducting coil, in the same manner as the other coils, as described above.

The present disclosure accordingly seeks to provide methods of manufacturing formerless, multi-coil, cylindrical superconducting magnets which are simpler and more precise than known methods and may be employed at reduced cost as compared to known methods. The magnets may be parallel, at least in the sense of having a common internal diameter, or a substantially common internal diameter in embodiments using a conically tapered mandrel.

The present disclosure also provides formerless, multi-coil, cylindrical superconducting magnets as may be produced by such methods. Although the specific embodiments described above each involve the use of multiple spacer rings 20, the disclosure may be applied to embodiments comprising a single spacer ring 20 between coils 50. The winding and impregnation tool as described with reference to the present disclosure such as mandrel 10 is more cost effective to manufacture than a conventional stepped mandrel, and will be easier to clean after impregnation of the coils. The formerless, multi-coil, cylindrical superconducting magnets of the present disclosure may also be manufactured at reduced wire cost as compared to conventional arrangements using stepped mandrels, due to the minimization of the diameter of the superconducting coil. The tooling required by the methods of the present disclosure may also be produced or obtained at a lower cost as compared to the tooling required for the conventional methods involving stepped mandrels.

What is claimed is:

1. A method for manufacturing a formerless, multi-coil, cylindrical superconducting magnet, comprising:
providing a cylindrical mandrel;
providing a plurality of spacer rings attached to an outer surface of the cylindrical mandrel at respective predetermined axial positions to provide a gap defining a volume of predetermined dimensions for winding of a coil;
winding superconducting wire into the gap to form the coil;
impregnating the coil with a thermosetting resin to provide an impregnated coil;
causing or allowing the thermosetting resin to cure to form an assembly comprising the plurality of spacer rings and the impregnated coil; and
separating the cylindrical mandrel from the assembly to provide the formerless, multi-coil, cylindrical superconducting magnet.

2. The method according to claim 1, further comprising:
coating the outer surface of the cylindrical mandrel with a release layer prior to attaching the plurality of spacer rings.

3. The method according to claim 1, wherein the outer surface of the cylindrical mandrel is conically tapered by a maximum of 1 degree.

4. The method according to claim 1, further comprising:
affixing end flanges or end plates to axial ends of the cylindrical mandrel prior to the act of winding the superconducting wire.

5. The method according to claim 4, wherein the act of affixing the end flanges or the end plates further defines adjacent gaps, and
wherein the superconducting wire is wound into the adjacent gaps to form further coils.

6. The method according to claim 1, further comprising:
applying a wrapper over the outer surface of the cylindrical mandrel prior to the act of attaching the plurality of spacer rings.

7. The method according to claim 6, wherein the wrapper provides electrical insulation on a radially inner surface of the coil.

8. The method according to claim 6, wherein the wrapper provides protection from mechanical damage on a radially inner surface of the coil.

9. The method according to claim 6, wherein the wrapper is bonded to the plurality of spacer rings and to the coil to prevent cracking at interfaces between coil and the plurality of spacer rings.

10. The method according to claim 1, wherein the act of providing the plurality of spacer rings comprises arranging the plurality of spacer rings at the respective predetermined axial positions using a number of comb tools, each one of the number of comb tools having recesses corresponding to the respective predetermined axial positions.

11. The method according to claim 10, wherein the number of comb tools align the plurality of spacer rings by further recesses therein, which engage with end flanges or end plates of the cylindrical mandrel prior, thereby defining the respective predetermined axial positions for the plurality of spacer rings.

12. The method according to claim 6, wherein the wrapper is formed by winding layers of a resin-impregnated cloth onto the outer surface of the cylindrical mandrel.

13. The method according to claim 6, wherein the wrapper is formed by winding preformed strips of resin-impregnated cloth onto the outer surface of the cylindrical mandrel.

14. The method according to claim 12, wherein:
the layers of resin-impregnated cloth comprise a first and a second layer of resin-impregnated cloth,
the first layer of resin-impregnated cloth comprises a first strip that is spirally wound over a length of the cylindrical mandrel in a first direction, and
the second layer of resin-impregnated cloth comprises a second strip that is spirally wound over the length of the cylindrical mandrel in a second direction that is opposite to the first direction.

15. The method according to claim 12, wherein the wrapper is provided by winding a filament of glass fiber, and resin-impregnating the filament before or after the winding of the filament.

16. The method according to claim 6, wherein a resin-impregnated material of the wrapper is cured and machined to a cylinder shape before providing the plurality of spacer rings on a machined surface of the wrapper.

17. The method according to claim 1, further comprising:
winding layers of overbind material on an outer surface of the coil that extend at least partially over outer surfaces of adjacent ones of the plurality of spacer rings.

18. The method according to claim 1, wherein the plurality of spacer rings are attached to the cylindrical mandrel by:
providing a threaded through hole at each one of several positions around the circumference of each one of the plurality of spacer rings;
providing a screw in each of the threaded through holes; and
tightening each screw to retain each one of the plurality of spacer rings in a predetermined position with respect to (i) the cylindrical mandrel, and (ii) other ones of the plurality of spacer rings.

19. The method according to claim 1, wherein the plurality of spacer rings are attached to the cylindrical mandrel by:
providing a through hole at each of several positions around the circumference of each one of the plurality of spacer rings;
introducing a hardening material through each one of the through holes;
causing or allowing the hardening material to harden to retain each one of the plurality of spacer rings in a predetermined position with respect to (i) a wrapper, and (ii) the cylindrical mandrel.

20. The method according to claim 1, wherein the plurality of spacer rings are attached to the cylindrical mandrel by:
providing a through hole at each of several positions around the circumference of each one of the plurality of spacer rings;
providing recesses in the outer surface of the cylindrical mandrel, each one of the through holes being arranged such that, when the through holes are aligned with corresponding recesses in the cylindrical mandrel, each one of the plurality of spacer rings is located in the respective predetermined axial position;
passing pins (i) through each one of the through holes, and (ii) partially into corresponding recesses.

21. The method according to claim 20, wherein the pins are friable, and
wherein the act of separating the cylindrical mandrel from the assembly comprises severing the pins from the assembly.

22. The method according to claim 21, wherein a portion of each pin length is hollow.

23. The method according to claim 21, wherein an outer surface of each pin is notched at a position corresponding to a shear plane.

24. The method according to claim 22, further comprising:
providing a screw thread on an outer and/or inner surface of each pin.

25. The method according to claim 20, further comprising:
extracting each one of the pins from the plurality of spacer rings (i) after curing of the thermosetting resin, and (ii) before separating the cylindrical mandrel from the assembly.

26. A formerless, multi-coil, cylindrical superconducting magnet assembly, comprising:
a plurality of spacer rings; and
a coil formed by superconducting wires,
wherein the multi-coil cylindrical superconducting magnet structure is formed by:
providing a cylindrical mandrel;
providing the plurality of spacer rings attached to an outer surface of the cylindrical mandrel at respective predetermined axial positions to provide a gap defining a volume of predetermined dimensions for winding of the coil;
winding the superconducting wire into the gap to form the coil;
impregnating the coil with a thermosetting resin to provide an impregnated coil;
causing or allowing the thermosetting resin to cure to form an assembly comprising the plurality of spacer rings and the impregnated coil; and
separating the cylindrical mandrel from the assembly to provide the formerless, multi-coil, cylindrical superconducting magnet.
